(19) United States
(12) Patent Application Publication
(10) Pub. No.: US 2009/0255570 A1
(43) Pub. Date: Oct. 15, 2009

(54) GLAZING ASSEMBLIES THAT INCORPORATE PHOTOVOLTAIC ELEMENTS AND RELATED METHODS OF MANUFACTURE

(75) Inventors: Robert C. Grommesh, St. Louis Park, MN (US); Roger D. O'Shaughnessy, Wayzata, MN (US)

Correspondence Address: INTELLECTUAL PROPERTY GROUP;FREDRIKSON & BYRON, P.A., 200 SOUTH SIXTH STREET, SUITE 4000, MINNEAPOLIS, MN, 55402, US

(73) Assignee: CARDINAL SOLAR TECHNOLOGIES COMPANY, Eden Prairie, MN (US)

(21) Appl. No.: 12/167,826

(22) Filed: Jul. 3, 2008

Related U.S. Application Data
(60) Provisional application No. 61/043,908, filed on Apr. 10, 2008.

(51) Int. Cl. H01L 31/042; B32B 37/14

(52) U.S. Cl. 136/251; 156/145

(57) ABSTRACT

A photovoltaic panel includes a substrate, a photovoltaic coating extending over, and being adhered to, a central region of a major surface of the substrate, and a flexible and electrically non-conductive film overlaying the photovoltaic coating, such that the photovoltaic coating is sandwiched between the film and the substrate. An assembly, which includes the photovoltaic panel, further includes a second substrate, which is joined to the first substrate, for example, by a seal member, such that an air space is enclosed between the film and the second substrate.

### PRIORITY CLAIM

The present application claims priority to provisional application Ser. No. 61/043,908 filed on Apr. 10, 2008, which is hereby incorporated, by reference, in its entirety

### TECHNICAL FIELD

The present invention pertains to glazing assemblies, and the like, which incorporate photovoltaic elements.

### BACKGROUND

Insulating glass (IG) units are glazing assemblies that typically include at least a pair of panels, or substrates, joined together such that a major surface of one of the substrates faces a major surface of the other of the substrates, and an air space is enclosed between the two substrates. At least one of the substrates is transparent, or light transmitting, and may bear a coating on the major surface that faces the major surface of the other substrate.

With the recent renewed interest in harnessing solar power, and the associated development of photovoltaic coatings for solar power cells, various configurations of glazing assemblies that incorporate photovoltaic coatings, have been proposed. These glazing assemblies, when configured as IG units, may be more cost effective than traditional laminated solar panels, for example, in that a bulk of the material (e.g. EVA), which encapsulates the photovoltaic coating, in the traditional solar panel, is replaced with an air space, thereby reducing material cost and manufacturing time, per unit. Yet, there is still a need for improved configurations of glazing assemblies that effectively incorporate photovoltaic coatings, in order to generate solar power.

### BRIEF SUMMARY

Embodiments of the present invention include photovoltaic panels, which are particularly suited for incorporation into IG unit—type glazing assemblies, as one of the substrates, and further include configurations of these glazing assemblies, as well as associated methods of manufacture. These embodiments may incorporate one or more cost effective elements to enhance protection against degradation of the photovoltaic coatings thereof, for example, resulting from contact with moisture and/or with other components of the glazing assembly, and/or to lend additional structural integrity.

According to some preferred embodiments, a photovoltaic coating extends over, and is adhered to, a central region of an inner major surface of a first substrate of a glazing assembly, and a flexible and electrically non-conductive film extends over approximately an entirety of the photovoltaic coating, such that the photovoltaic coating is sandwiched between the film and the first substrate; the glazing assembly further includes a second substrate which is joined to the first substrate, along corresponding peripheral regions thereof, by a seal member, such that an air space is located between an exposed surface the film and the second substrate. The film may be pre-formed, for example, from a polyethylene, a polypropylene or a polyester material, and may have a thickness between approximately 0.001 inch and approximately 0.015 inch. According to further embodiments, the first substrate, the photovoltaic coating and the film are initially assembled into a photovoltaic panel, having the aforementioned configuration, for subsequent incorporation into a glazing assembly, by joining the peripheral region of another substrate to the peripheral region of the first substrate, which is essentially free of the coating and the film. Prior to joining the other substrate of the glazing assembly to the photovoltaic panel, a desiccant material may be adhered to the exposed surface of the film.

### BRIEF DESCRIPTION OF THE DRAWINGS

The following drawings are illustrative of particular embodiments of the present invention and therefore do not limit the scope of the invention. The drawings are not to scale (unless so stated) and are intended for use in conjunction with the explanations in the following detailed description. Embodiments of the present invention will hereinafter be described in conjunction with the appended drawings, wherein like numerals denote like elements.

FIG. 1 is a perspective view of a glazing assembly, according to some embodiments of the present invention.

FIG. 2 is a schematic plan view of either of the substrates of the assembly shown in FIG. 1.

FIG. 3 is a perspective view of a portion of the assembly shown in FIG. 1.

FIG. 4 is a section view through section line A-A of FIG. 1, according to some embodiments.

FIG. 5 is a cross-section of a portion of the assembly shown in FIG. 4, according to one embodiment.

FIG. 6 is a flow chart outlining some assembly methods of the present invention.

### DETAILED DESCRIPTION

The following detailed description is exemplary in nature and is not intended to limit the scope, applicability, or configuration of the invention in any way. Rather, the following description provides practical illustrations for implementing exemplary embodiments of the present invention.

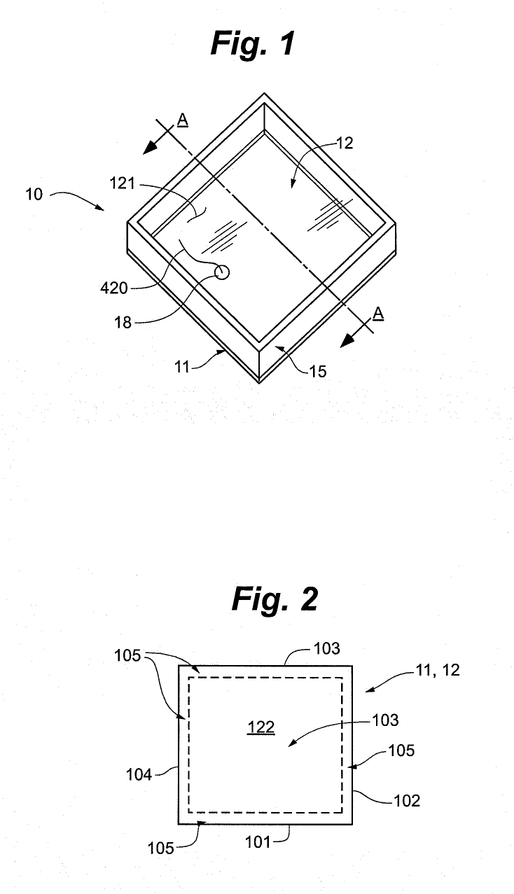

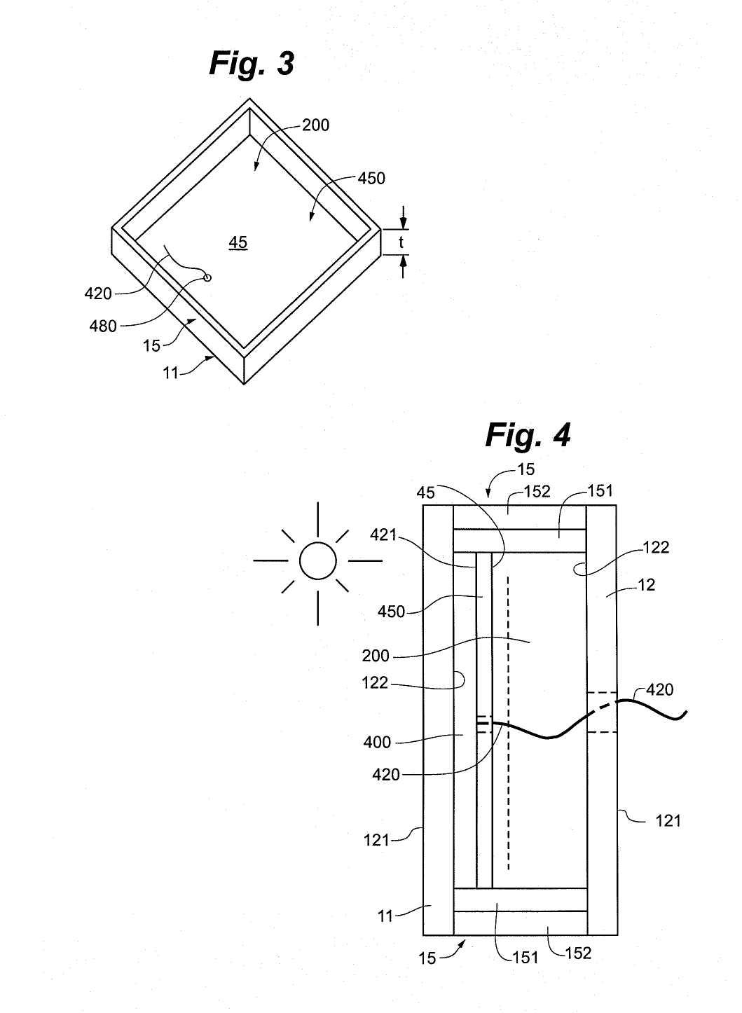

FIG. 1 is a perspective view of a glazing assembly 10, according to some embodiments of the present invention. FIG. 1 illustrates assembly 10 including a first substrate 11, a second substrate 12 and a seal system 15, which joins substrates 11, 12 together; a first major surface 121 of each of substrates 11, 12, face outward or away from one another, and a second major surface 122 of each of substrates 11, 12 faces inward, or toward one another, being spaced apart from one another by a seal system 15. FIG. 2 is a schematic plan view of either of the substrates 11, 12 of assembly 10. FIG. 2 illustrates second, or inner major surface 122 of substrate 11/12 having a central region 103 and a peripheral region 105, which are delineated from one another by the dashed line. According to the illustrated embodiment, seal system 15 joins first substrate 11 to second substrate 12 along peripheral regions 105 of inner major surfaces 122. FIG. 3 is a perspective view of assembly 10, having second substrate 12 removed to show an air space 200 that is enclosed between substrates 11, 12 when they are joined together by seal system 15.

FIG. 3 further illustrates seal system 15 having a thickness t, which, according to some embodiments, is between approximately 0.01 inch and approximately 0.1 inch, preferably approximately 0.04 inch, but could be up to 1.5 inches in alternate embodiments. According to some embodiments, seal system 15 is formed, at least in part, from a polymer material, for example, a thermoplastic, such as a Kommerling TPS, having low moisture vapor transmission properties, for example, resulting in a moisture vapor transmission rate (MVTR) therethrough, which does not exceed approximately 20 g mm/m²/day. Other examples of these polymer materials include, without limitation, butyl rubber, ionomers, ethylene methacrylic acid copolymers and polyisobutylenes, the ethylene methacrylic acid copolymers being preferred for their excellent adhesion properties, which are desirable to hold together glazing assemblies such as assembly 10. Some examples of these preferred materials, which are commercially available, are Sentry Glas® Plus, available from DuPont, and PRIMACOR™, available from Dow Chemical. According to some alternate embodiments, seal system 15 includes a first seal member 151, which extends about an inner portion of peripheral region 105, and a second seal member 152, which extends about an outer portion of perimeter region 105, for example as illustrated in FIG. 4.

FIG. 4 is a section view through section line A-A of FIG. 1, according to some embodiments. With reference to FIG. 4, first seal member 151 may be affixed to opposing peripheral regions 105 of inner major surfaces 122 of substrates 11, 12, in order to join substrates 11, 12 to one another, leaving an outer perimeter channel between the outer portions of the opposing peripheral regions 105 to be later filled with second seal member 152. First seal member 151 is preferably formed from a polymer material, which has low moisture vapor transmission properties, for example, any of those referenced above; and second seal member 152 may be formed of any material having suitable adhesive properties, for example, silicone, polysulfide or polyurethane.

According to some preferred embodiments, first substrate 11 is light transmitting, for example, formed from glass or a plastic material, such as polycarbonate, and second substrate 12 may be similarly formed or may be opaque. According to some alternate embodiments, second substrate is light transmitting, for example, formed from glass or a plastic material, such as polycarbonate, and first substrate 11 may be similarly formed or may be opaque. Although the term “glazing” typically connotes incorporation of a glass panel or substrate, the use of the term is not so limited in the present disclosure, and glazing assemblies of the present invention may incorporate any light transmitting substrate, for example, formed from a plastic such as polycarbonate. FIG. 4 further illustrates glazing assembly 10 including a photovoltaic coating 400 extending over, and being adhered to, inner major surface 122 of first substrate 11, and a flexible and electrically non-conductive film 450 extending over photovoltaic coating 400, such that coating 400 is sandwiched between substrate 11 and film 450, and airspace 200 is located between an exposed surface 45 of film and second substrate 12.

Film 450 may be formed, preferably pre-formed prior to application over coating 400, from a polyolefin material, for example, a polyethylene or polypropylene, or from a polyester material, and may have a thickness between approximately 0.001 inch and approximately 0.015 inch, preferably approximately 0.0035 inch. According to some preferred embodiments, film 450, when pre-formed, includes an adhesive backing 421 for adhering film 450 to coating 400, and may be supplied in rolls. Adhesive backing 421 may be formed by an acrylic adhesive or by a rubber-based adhesive, or by any other suitable adhesive known to those skilled in the art, and may extend over approximately an entirety of the interface between film 450 and coating 400 or just over selected portions of the interface. Alternatively, film 450 may be otherwise secured over coating 400, for example, a perimeter of film 450 may be captured between a portion of seal system 15 and first substrate.

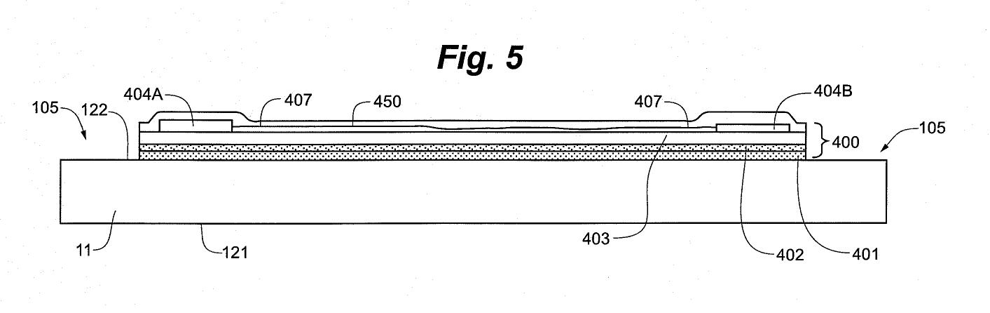

According to embodiments of the present invention, substrate 11, photovoltaic coating 400 and flexible and electrically non-conductive film 450 form a photovoltaic panel of assembly 10 so that assembly 10 can function as a solar power cell. Photovoltaic coating 400 may be of any type known to those skilled in the art, either of the conventional type, for example, including an array of silicon wafers interconnected by soldered conductors, or of the ‘thin film’ type, for example, including several thin film semiconductor layers, which are patterned to form electrically interconnected cells. An embodiment of the present invention, which includes coating 400 as a thin film CdTe type is described in conjunction with FIG. 5, however, it should be appreciated that alternate embodiments may incorporate coating 400 as a thin film Cu(InGa)Se₂ (CIGS) type or amorphous silicon(a-Si) type.

Because film 450 is enclosed between first and second substrates 11, 12 of glazing assembly 10, film 450 need not have a durability that is otherwise required for exposed polymer back skins employed by some photovoltaic panels known in the art. However, according to some preferred embodiments, film 450 has properties such that the integrity of film 450 is maintained under thermal cycling conditions, for example, temperatures ranging between approximately −40° C. and approximately 85° C., over a life span of up to, and preferably exceeding, approximately 20 years.

With further reference to FIG. 4, a dotted line schematically represents an optional desiccant material enclosed within airspace 200 to absorb any moisture that may pass through seal system 15. The desiccant material, either in sheet or strip form, or granular form, either embedded in a matrix or packaged in a sack, may be ‘free-floating’ in airspace 200, or adhered to exposed surface 45 of film 450 or to second substrate 12, or otherwise present in airspace 200. The desiccant material, in combination with the aforementioned relatively low MVTR of seal system 15, may prevent moisture build-up within airspace 200 that can lead to corrosion of certain elements of photovoltaic coating 400. According to some embodiments, a plurality of desiccant beads are adhered to a surface of a sheet-like material, or tape, which is then adhered to exposed surface 45 of film 450.

FIG. 5 is a cross-section of the photovoltaic panel portion of the assembly shown in FIG. 4, according to one embodiment. FIG. 5 illustrates coating 400 including a first layer 401 formed by a transparent conductive oxide (TCO), for example, comprising Tin oxide (SnO₂), which is overlaid with a semiconductor layer 402, for example, comprising two ‘sub-layers’: Cadmium sulfide (CdS; ‘window’ layer; n-type), extending adjacent to first layer 401, and Cadmium Telluride (CdTe; absorbing layer; p-type), overlaying the Cadmium sulfide sub-layer. FIG. 5 further illustrates an electrical contact layer 403, for example, comprising nickel, which extends between the Cadmium Telluride sub-layer of semiconductor layer 402, and a pair of bus bars 404A, 404B. Bus bars 404A, 404B may each be formed from a copper tape, for example, approximately 0.003-0.007 inch thick, which are adhered to contact layer 403, for example, by a conductive acrylic adhesive. Bus bars 404A, 404B preferably extend approximately parallel to one another along opposing edge portions of coating 400; an internal insulated conductor 407 is coupled to each bus bar 404A, 404B, and conductors 407 terminate near an electrical access opening 480 in film 450 (FIG. 3). Film 450 can provide additional retention for holding bus bars 404A, 404B in intimate contact with contact layer 403 and for securing insulated conductors 407 against layer 400. An electrical lead 420, which is shown in FIGS. 1, 3 and 4, includes a pair of isolated conductive lead wires to collect power from the photovoltaic panel; each lead wire is coupled to a corresponding conductor 407, for example, via soldering to a respective terminal thereof in proximity to opening 480.

With reference to FIG. 1, second substrate 12 is shown including an opening 18, which is approximately aligned with electrical access opening 480, and extends through second substrate 12, to allow further passage of lead 420 out from assembly 10. A diameter of openings 480, 18 may be between approximately ¼ inch and approximately 1 inch. According to the illustrated embodiment, after routing lead 420 out from system 10, through opening 18, a potting material is applied around lead 420, to seal off opening 18. Examples of suitable potting materials include, without limitation, polyurethane, epoxy, polyisobutylene, and any low MVTR material. According to alternate embodiments, one or both of openings 480, 18 are not necessary and lead 420 extends out from assembly 10 through an opening in seal system 15 or through an opening between seal system 15 and one of substrates 11, 12, or through an opening in first substrate 11.

According to some preferred embodiments of the present invention, the flexibility of film 450, in combination with a tear strength thereof, is suited to hold substrate 11 and photovoltaic coating 400 together in case substrate 11 is fractured, thereby containing fragments of the fractured substrate 11 to prevent a scattering of potentially toxic elements of photovoltaic coating 400, for example, Cadmium. Furthermore, in the event that substrate 12 is broken, the electrical insulating properties of film 450 preferably electrically isolates coating 400 and electrically charged conductors 407, which are coupled to bus bars 404A,B of coating 400, thereby preventing potential injury to one handling the broken assembly. Film 450 may further protect the semiconductor sub-layers of coating 400 if, during relatively cold temperature conditions, the air space between substrates 11, 12 shrinks such that substrates 11, 12 come into contact. According to some embodiments, in which sun light is received by coating 400 through first substrate 11, for example, in the case of the CdTe type of coating (FIG. 5), and second substrate 12 is translucent or transparent, flexible film 450 is opaque to provide a more aesthetically pleasing uniform appearance to the photovoltaic panel, when viewed through second substrate 12. According to those embodiments in which coating 400 is the CIGS type, since sun light is received by the coating 400 through second substrate 12 and through film 450, film 450 needs to light transmitting.

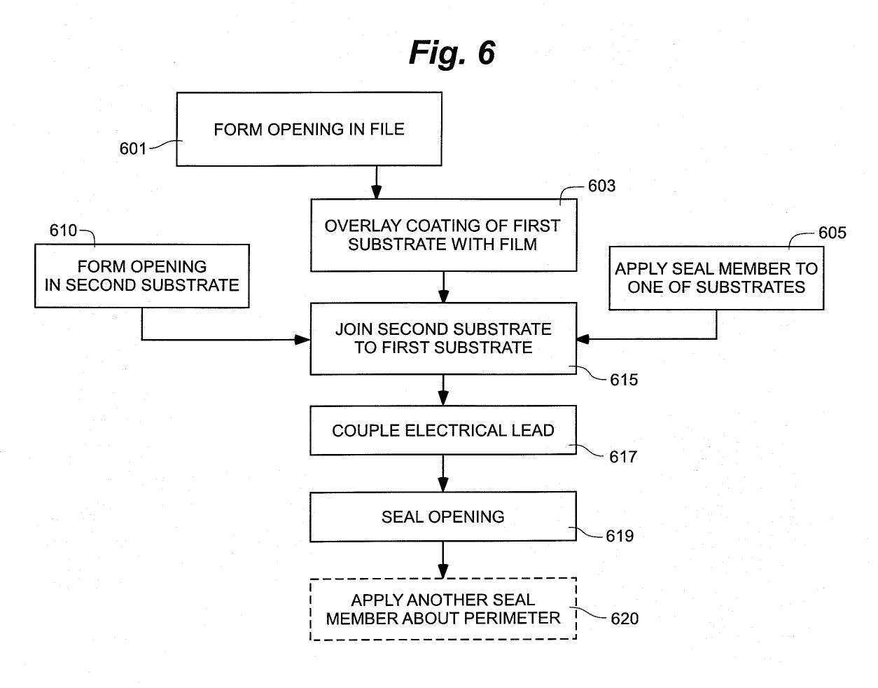

FIG. 6 is a flow chart outlining some assembly methods of the present invention, which start with a first substrate, for example, first substrate 11, that has a photovoltaic coating, for example, coating 400 (FIG. 4), already formed over a central region of a major surface thereof, for example, central region 103 of surface 122 (FIG. 2). This pre-formed photovoltaic coating preferably extends over the central region of the major surface of the first substrate, without significantly encroaching on a peripheral region of the surface, for example, region 105 (FIGS. 2 and 5), so as to maintain exposure of a native surface of the substrate for fixation to a sealing member, for example, included in sealing system 15, which joins the first substrate to an opposing second substrate, for example, second substrate 12. According to the outlined method, an opening is formed in a sheet of flexible and electrically non-conductive film, for example, electrical access opening 480 in film 450 (FIG. 3), per step 601, and then the photovoltaic coating of the first substrate is overlaid with the film, per step 603. As previously described, the film is adhered to the photovoltaic coating, preferably by means of an adhesive backing pre-formed on a surface of the film. The overlaid film preferably covers an entirety of the photovoltaic coating, for example, as shown in FIG. 5, while leaving enough of the peripheral region of the surface of the first substrate, for example region 105, free for fixation with a sealing member that will join the first substrate to the second substrate. However, according to some embodiments, the film may not cover a portion of a perimeter of the coating, which portion may extend between the sealing member and the first substrate.

According to the outlined method, following step 603, the seal member is applied to one of first and second substrates, per step 605, and then second substrate is joined to first substrate, per step 615. Joining the first substrate to the second substrate, per step 615, includes pressing the two substrates together, with the seal member sandwiched therebetween along the peripheral regions of the facing major surfaces, while maintaining an air space, for example air space 200 (FIG. 4), between the central regions of the facing major surfaces; heat may be applied, along with pressure, to securely affix the seal member to each of the substrates. Prior to joining the second substrate to the first substrate, per step 615, an opening, for example, opening 18 (FIG. 1), is formed in second substrate, per step 610, according to the outlined method. The opening in the second substrate is preferably aligned with the opening in the film when the second substrate is joined to the first substrate, per step 615.

After joining the second substrate to the first substrate, an external lead, for example, lead 420 (FIGS. 1, 3 and 4), is coupled, through the openings in the film and the second substrate, to internal conductors, for example, conductors 407 (FIG. 5), which extend from the bus bars of the photovoltaic coating, per step 617, as previously described. According to step 619, a potting material is applied around the lead at the opening to seal of the opening, also as previously described; the potting material may further form a strain relief for the lead adjacent to the second substrate, or a separate strain relief member may be installed about the lead. Finally, if the aforementioned seal member, which joins the first substrate to the second substrate, is a first of a pair of seal members in a seal system, for example, seal system 15 illustrated in FIG. 4, the second seal member, for example, seal member 152, is applied about a perimeter of the first seal member in between the first and second substrates, per optional step 620.

In the foregoing detailed description, the invention has been described with reference to specific embodiments. However, it may be appreciated that various modifications and changes can be made without departing from the scope of the invention.

1. A glazing assembly comprising:
a first substrate including an inner major surface, the inner major surface including a central region and a peripheral region;
a photovoltaic coating extending over, and being adhered to, the central region of the inner major surface of the first substrate;
a flexible and electrically non-conductive film extending directly over approximately an entirety of the photovoltaic coating, such that the photovoltaic coating is sandwiched between the film and the first substrate;
a second substrate opposing the first substrate and including an inner major surface, which faces the inner major surface of the first substrate, the inner major surface of the second substrate including a central region, approximately aligned with the central region of the inner major surface of the first substrate, and a peripheral region, approximately aligned with the peripheral region of the inner major surface of the first substrate; and
a seal member joining the first substrate to the second substrate along the peripheral regions of the inner major surfaces thereof, such that an air space is enclosed between the film and the second substrate.

2. The assembly of claim 1, wherein the film comprises a material selected from the group consisting of: polyethylene, polypropylene and polyester.

3. The assembly of claim 1, wherein the film is pre-formed and includes an adhesive backing for adhering the film to the photovoltaic layer.

4. The assembly of claim 1, wherein the film is opaque.

5. The assembly of claim 1, wherein a thickness of the film is between approximately 0.001 inch and approximately 0.015 inch.

6. The assembly of claim 1, wherein the film includes an electrical access opening extending therethrough.

7. The assembly of claim 1, wherein the second substrate includes an opening extending therethrough, the opening being located in the central region of the inner major surface thereof.

8. The assembly of claim 1, wherein a width of the air space between the first and second substrates is approximately 0.04 inch.

9. The assembly of claim 1, further comprising a desiccant material adhered to the film and located within the air space.

10. The assembly of claim 1, wherein the first substrate is formed from a light transmitting material.

11. The assembly of claim 1, wherein the second substrate is formed from a light transmitting material.

12. A photovoltaic panel for a glazing assembly, the panel comprising:
a substrate including a major surface, the major surface including a central region and a peripheral region extending completely about the central region;
a photovoltaic coating extending over, and being adhered to, the central region of the major surface of the substrate;
a flexible and electrically non-conductive film being adhered to the photovoltaic coating and extending over approximately an entirety of the photovoltaic coating, such that the photovoltaic coating is sandwiched between the film and the substrate; and
a plurality of desiccant beads adhered to an exposed surface of the film;
wherein the peripheral region of the major surface of the substrate is free of the photovoltaic coating and the film.

13. The panel of claim 12, wherein the film comprises a material selected from the group consisting of: polyethylene, polypropylene and polyester.

14. The panel of claim 12, wherein the film is pre-formed and includes an adhesive backing for adhering the film to the photovoltaic layer.

15. The panel of claim 12, wherein the film is opaque.

16. The panel of claim 12, wherein a thickness of the film is approximately 0.0035 inch.

17. The panel of claim 12, wherein a thickness of the film is between approximately 0.001 inch and approximately 0.015 inch and the film is formed of a material comprising polyethylene.

18. The panel of claim 12, wherein the film includes an opening extending therethrough.

19. The panel of claim 12, wherein the substrate is formed from a light transmitting material.

20. A method for forming a glazing assembly, the method comprising:
overlaying a photovoltaic coating with a flexible and electrically non-conductive film, the photovoltaic coating being adhered to a central region of a major surface of a first substrate and the central region being surrounded by a peripheral region of the major surface;
adhering a plurality of desiccant beads to an exposed surface of the film; and
joining a second substrate to the first substrate, along the peripheral region thereof, such that an air space is enclosed between the film and the second substrate.

21. The method of claim 20, wherein overlaying the photovoltaic coating with the film comprises adhering an adhesive-backed surface of the film to the photovoltaic coating.

22. The method of claim 20, wherein joining the second substrate to the first substrate comprises affixing a seal member to the peripheral region of the major surface of the first substrate and to a corresponding peripheral region of a major surface of the second substrate.

23. The method of claim 20, further comprising forming an opening through the film, prior to overlaying the photovoltaic coating with the film.

24. The method of claim 20, further comprising forming an opening through the second substrate prior to joining the second substrate to the first substrate.

25. The method of claim 20, further comprising:
forming an opening through the film for access to a bus bar of the photovoltaic coating;
forming an opening through the second substrate; and
coupling an electrical lead wire to the bus bar of the photovoltaic coating through the openings of the film and the second substrate.
